(19) United States
(12) Patent Application Publication
(10) Pub. No.: US 2007/0158732 A1
(43) Pub. Date: Jul. 12, 2007

(54) Flash memory device having vertical split gate structure and method for manufacturing the same

(75) Inventor: Sung Jin Kim, Yeonje-gu (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu Electronics Co., Ltd.

(21) Appl. No.: 11/648,382

(22) Filed: Dec. 28, 2006

(30) Foreign Application Priority Data
Dec. 29, 2005 (KR) 10-2005-0134122

(51) Int. Cl. H01L 29/76

(52) U.S. Cl. 257/314

(57) ABSTRACT

Disclosed are a flash memory device having a vertical split gate structure and a method for manufacturing the same. The flash memory device includes a first trench formed in an active region of a semiconductor substrate and including a pair of opposite sidewalls, a second trench formed in the middle of the first trench so as to be deeper than the first trench and including a pair of opposite sidewalls, a pair of opposite floating gates formed along the pair of sidewalls of the first trench, a pair of opposite control gates formed along the pair of sidewalls of the paired floating gates 160a and along the pair of sidewalls of the second trench, a common source diffusion region formed in the active region under the pair of control gates, a drain diffusion region formed in the active region adjacent to the pair of floating gates, and a common source line electrically contacted with the common source diffusion region and formed between the pair of control gates.

### BACKGROUND OF THE INVENTION

1. Field of the Invention

The present invention relates to a semiconductor device and a method for manufacturing the same. More particularly, the present invention relates to a flash memory device having a vertical split gate structure and a method for manufacturing the same.

2. Description of the Related Art

A flash memory is a sort of programmable read-only memory (PROM) in which data can be electrically rewritten.

This flash memory is called a non-volatile memory because stored information is retained when the power is turned off. In this respect, the flash memory is different from a dynamic random access memory (DRAM) or a static random access memory (DRAM) The flash memory can be divided into a NOR type structure and a NAND type structure according to a cell array structure, wherein the NOR type structure has cells arranged in parallel between the bit line and the ground, whereas the NAND type structure has cells arranged in series between the bit line and the ground.

The NOR type flash memory having the parallel structure is widely used for booting a mobile phone because high-speed random access can be provided when reading operation is performed.

The NAND type flash memory having the series structure is suitable for storing data due to a high writing speed in spite of a low reading speed, and is advantageous for miniaturization.

Further, the flash memory can be divided into a stack gate type and a split gate type in accordance with the structure of a unit cell, and can be divided into a floating gate device and a silicon-oxide-nitride-oxide-silicon (SONOS) device in accordance with the shape of a charge storage layer.

Meanwhile, the NOR type flash memory is designed such that memory cells are connected in parallel to the bit line.

Therefore, if the threshold voltage of a cell transistor is lower than voltage (typically, 0 V) applied to the control gate electrode of an unselected memory device, current flows between the source and drain irrespective of on or off of a selected memory device. Accordingly, the malfunction in which all memory devices are read to be an on state can occur.

Further, in order to produce voltage required when a program is executed by channel hot carrier injection, a high-capacity boosting circuit is required.

To solve this problem, a gate structure that is generally called a split gate has been proposed. FIG. 1 schematically illustrates the section of a unit cell transistor in which a split gate having a two-poly structure is formed. Referring to FIG. 1, a source diffusion region 12s and a drain diffusion region 12d are formed in the active region of a substrate 10. A floating gate 16 is formed above the substrate 10 via a gate insulating layer 14 around the drain diffusion region 12d. Further, a control gate 22 extends from an upper portion to a sidewall of the floating gate 16, and is formed parallel to the substrate 10 on one end thereof. The control gate 22 is insulated from the floating gate 16 by means of an intergate insulating layer 18. A tunnel insulating layer 20 is interposed between the substrate 10 and the control gate 22.

In the memory device having the split gate structure illustrated in FIG. 1, when voltages Vth and Vpp are applied to the control gate 22 and the drain diffusion region 12d respectively, the current flows from the source diffusion region 12s to the drain diffusion region 12d. The electrons producing the current are injected into the floating gate 16 through the insulating layer by means of electrostatic force from the floating gate 16, so that a program is executed. Further, when a high voltage is applied to the control gate 22, and the source and drain diffusion regions 12s and 12d are grounded, the electrons charged in the floating gate 16 give rise to Fowler-Nordheim (F-N) tunneling from the floating gate 16 by means of the high voltage applied to the control gate 22, so that the data is erased.

However, in the split gate device, because a channel of the control gate is formed by a lithography process, it is difficult to accurately control a length of the channel. Hence, when the control gate is driven, the voltage and current are inevitably varied. Further, the one end of the control gate is formed in parallel along a surface of the substrate, so that there is a limitation in reducing a cell size.

### SUMMARY OF THE INVENTION

Accordingly, the present invention is directed to a flash memory device having a vertical split gate structure and a method for manufacturing the same, in which the size of a memory cell is remarkably reduced.

According to an aspect of the present invention, there is provided a method for manufacturing a flash memory device having a vertical split gate structure. The method includes the steps of (a) forming a first trench including a pair of opposite sidewalls in an active region of a semiconductor substrate, (b) forming a pair of opposite floating gates on the pair of sidewalls of the first trench respectively, (c) forming a second trench including a pair of opposite sidewalls in the middle of the first trench exposed between the pair of floating gates, (d) forming a pair of opposite control gates on the pair of sidewalls of the paired floating gates 160a and on the pair of sidewalls of the second trench, (e) forming a common source diffusion region on a bottom of the second trench exposed between the pair of control gates, and (f) forming a drain diffusion region in the active region adjacent to the pair of floating gates.

The method may include the step of forming a tunnel insulating layer interposed between the first trench and the floating gates before step (b). Further, the method may include the step of forming an intergate dielectric layer interposed between the floating gates and the control gates before step (d). Also, the method may include the step of forming a pair of opposite insulating spacers on first sidewalls of the paired control gates before step (e). In addition, the method may include the step of forming a common source line electrically contacted with the common source diffusion region between the pair of insulating spacers after step (e).

According to another aspect of the present invention, there is provided a flash memory device having a vertical split gate structure. The flash memory device includes a first trench formed in an active region of a semiconductor substrate and including a pair of opposite sidewalls, a second trench formed in the middle of the first trench so as to be deeper than the first trench and including a pair of opposite sidewalls, a pair of opposite floating gates formed along the pair of sidewalls of the first trench, a pair of opposite control gates formed along the pair of sidewalls of the paired floating gates 160a and along the pair of sidewalls of the second trench, a common source diffusion region formed in the active region under the pair of control gates, a drain diffusion region formed in the active region adjacent to the pair of floating gates, and a common source line electrically contacted with the common source diffusion region and formed between the pair of control gates.

Here, the flash memory device may further include a tunnel insulating layer interposed between the first trench and the floating gates, and an intergate dielectric layer interposed between the floating gates and the control gates. The flash memory device may further include a gate insulating layer interposed between the control gates and the second trench, and insulating spacers interposed between the control gates and the common source line.

### BRIEF DESCRIPTION OF THE DRAWINGS

FIG. 1 is a sectional view illustrating a conventional flash memory device having a split gate structure; and

FIGS. 2A through 2I are sectional views for explaining a method for manufacturing a flash memory device having a vertical split gate structure in accordance with the present invention.

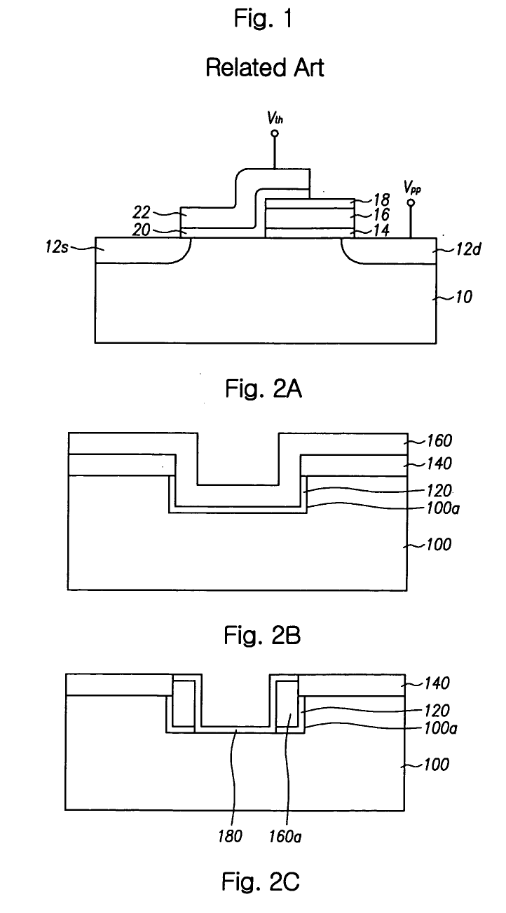

### DETAILED DESCRIPTION OF THE PREFERRED EMBODIMENTS

Hereinafter, a flash memory device having a vertical split gate structure and a method for manufacturing the same in accordance with exemplary embodiments of the present invention will be described in detail with reference to the accompanying drawings.

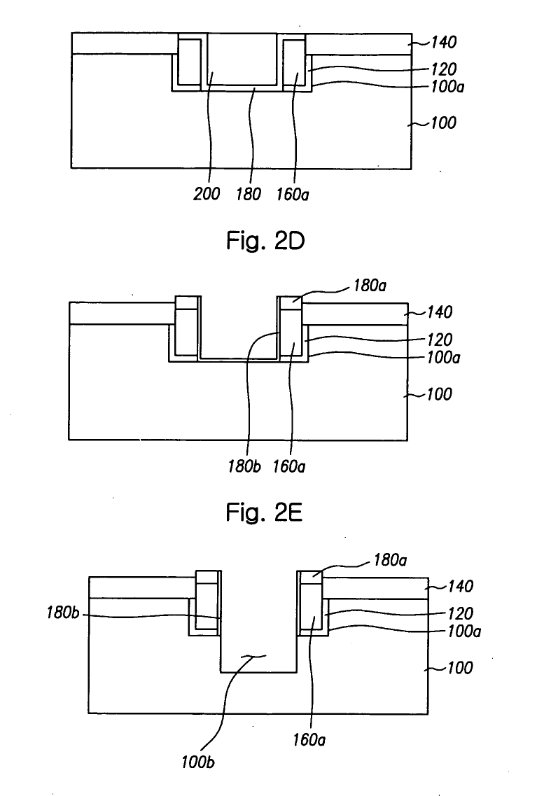

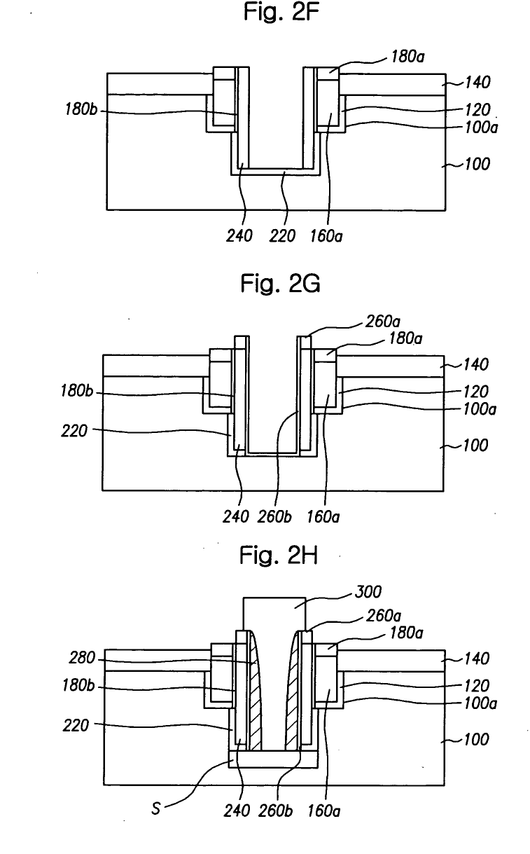

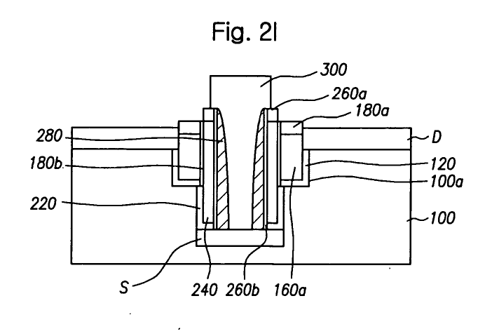

Referring to FIG. 2A, an isolation layer (not shown) such as a shallow trench isolation (STI) layer is formed on a silicon semiconductor substrate 100, thereby defining an-active region. A first insulating layer 140 is formed on the substrate 100, and then a first trench 100a is formed in the substrate 100 through a lithography process and an etching process. In the case of using a silicon nitride layer as the first insulating layer 140, a silicon oxide layer may be formed as a buffer layer between the first insulating layer 140 and the substrate 100. After the first trench 100a is formed, the threshold voltage of a cell is adjusted through an ion implantation process. Thereafter, an inner wall of the first trench 100a is oxidized to form a silicon oxide layer 120 as a tunnel insulating layer.

After the tunnel insulating layer 120 is formed, a polysilicon layer 160 is formed on a top surface of the substrate 100. When the polysilicon layer 160 is etched back, as illustrated in FIG. 2B, a pair of opposite floating gates 160a is formed on sidewalls of the first trench 100a. At this time, in the process of etching back the polysilicon layer 160, part of the silicon oxide layer 120 formed on the bottom of the first trench 100a can be removed. After the floating gates 160a are formed, both polysilicon of the silicon substrate 100 exposed by the removal of the silicon oxide layer 120 and polysilicon of the floating gates 160a are oxidized to form another silicon oxide layer 180.

Next, as illustrated in FIG. 2C, a second insulating layer 200 is filled between the pair of floating gates 160a on which the silicon oxide layer 180 is formed. The ion implantation process is performed again using the second insulating layer 200 as a mask, thereby implanting a dopant into upper portions of the floating gates 160a. When the dopant is implanted into the floating gates 160a, the bottom of the first trench 100a is masked by the second insulating layer 200, so that a charge balance of the silicon substrate to which the threshold voltage is adjusted is not influenced.

Subsequently, as illustrated in FIG. 2D, the second insulating layer 200 is selectively removed, and then the silicon oxide layer formed at the upper portions of the floating gates 160a is additionally formed to have a thicker thickness by means of an oxidation process. In the oxidation process, the upper portions of the floating gates 160a into which the dopant is implanted in the previous process can be formed to be thicker than the silicon oxide layer formed on the sidewalls of the floating gates 160a. Therefore, capping oxide layers 180a are formed at the upper portions of the floating gates 160a at a thick thickness, and sidewall oxide layers 180b used as intergate dielectric layers are formed on the sidewalls of the floating gates 160a.

Then, as illustrated in FIG. 2E, the bottom of the first trench 100a is etched using the capping oxide layers 180a as a mask, thereby forming a second trench 100b. The second trench 100b is formed in the middle of the first trench 100a and at a depth greater than that of the first trench 100a. The silicon substrate 100 exposed by the second trench 100b is oxidized, thereby forming a gate oxide layer 220. Then, the polysilicon layer is again deposited on the top surface of the substrate, and then is etched back, thereby forming control gates 240. As illustrated in FIG. 2F, the control gates 240 vertically extends from sidewalls of the second trench 100b to sidewalls of the floating gates 160a. Afterwards, in order to increase conductivity of the control gates 240, the ion implantation process is performed on the upper portions of the control gates 240.

As illustrated in FIG. 2G, when outer walls of the pair of opposite control gates 240 are oxidized, thick silicon oxide layers 260a are formed on the upper portions of the control gates 240 into which the dopant is implanted, and relatively thin silicon oxide layers 260b are formed on the sidewalls thereof.

Next, as illustrated in FIG. 2H, an insulating layer is deposited on the top surface of the substrate, and then insulating spacers 280 are formed on sidewalls of the opposite control gates 240 respectively by means of the etch-back process. Then, the dopant is implanted into the bottom of the second trench 100b exposed between the pair of insulating spacers 280, thereby forming a common source diffusion region S. Memory cells neighboring the common source diffusion region S are connected in parallel. Then, a gap between the insulating spacers 280 is filled with a conductive material, thereby forming a common source line 300. The common source line 300 extends in a direction perpendicular to a word line, so that a NOR type memory array, in which a plurality of memory cells are connected in parallel by means of the common source line 300, is formed.

Finally, as illustrated in FIG. 2I, the first insulating layer 140 formed on the substrate is removed, and the dopant is implanted into the active region of the exposed substrate, thereby forming a drain diffusion region D.

The split gate structure formed by the above-described method is perpendicular to the substrate when viewed in section, so that it can greatly reduce the cell size compared to the conventional split gate structure.

Further, the floating gates can be self-aligned on the sidewalls of the first trench, and the control gates can be self-aligned on the sidewalls of the second trench and the sidewalls of the floating gates as well.

Accordingly, the floating gates can be formed at a fine line width without depending on the lithography process, and the variation of the driving voltage caused by the misalignment of the control gates can be prevented.

Further, the common source line is formed of the conductive material without applying conventional self-aligned source (SAS) technology, so that the resistance of the source line is greatly reduced.

It will be apparent to those skilled in the art that various modifications and variations can be made in the present invention. Thus, it is intended that the present invention covers the modifications and variations of this invention provided they come within the scope of the appended claims and their equivalents.

What is claimed is:

1. A method for manufacturing a flash memory device, the method comprising the steps of:
forming a first trench including a first pair of opposed sidewalls in an active region of a semiconductor substrate;
forming a pair of opposed floating gates on the first pair of sidewalls of the first trench;
forming a second trench including a second pair of opposed sidewalls in a surface of the first trench exposed between the pair of floating gates;
forming a pair of opposed control gates on the pair of opposed floating gates and on the second pair of sidewalls;
forming a common source diffusion region on a bottom of the second trench exposed between the pair of control gates; and
forming a drain diffusion region in the active region adjacent to each floating gate.

2. The method as claimed in claim 1, further comprising the step of forming a tunnel insulating layer on the first pair of sidewalls before forming the pair of opposed floating gates.

3. The method as claimed in claim 1, further comprising the step of forming a dielectric layer on the floating gates and before forming the pair of opposed control gates.

4. The method as claimed in claim 1, further comprising the step of forming a pair of opposed insulating spacers on the pair of opposed control gates.

5. The method as claimed in claim 4, further comprising the step of forming a common source line electrically contacted with the common source diffusion region between the pair of opposed insulating spacers.

6. The method as claimed in claim 5, wherein the common source line comprises a conductive material that is continuous with an adjacent common source diffusion region.

7. The method as claimed in claim 6, wherein the common source line is on the substrate in an area outside of the active region or between adjacent flash memory devices.

8. The method as claimed in claim 1, wherein the second trench is formed in the middle of the first trench exposed between the pair of floating gates.

9. The method as claimed in claim 1, wherein the second trench is formed in the substrate, in an exposed bottom surface of the first trench.

10. The method as claimed in claim 1, wherein the second trench has a bottom surface below a bottom surface of the first trench.

11. The method as claimed in claim 1, wherein the flash memory device has a split gate structure.

12. A flash memory device, comprising:
a pair of opposed floating gates on first opposed sidewalls of a first trench in an active region of a semiconductor substrate;
a pair of opposed control gates on the pair of floating gates and along second opposed sidewalls of a second trench, the second trench being in the first trench and having a depth greater than the first trench;
a common source diffusion region in the active region under the pair of control gates;
a drain diffusion region in the active region adjacent to each of the floating gates; and
a common source line in electrical contact with the common source diffusion region, between the pair of control gates.

13. The flash memory device as claimed in claim 12, further comprising a tunnel insulating layer between each of the first opposed sidewalls and a corresponding floating gate.

14. The flash memory device as claimed in claim 12, further comprising a dielectric layer between each of the floating gates and a corresponding control gate.

15. The flash memory device as claimed in claim 12, further comprising a gate insulating layer between each control gate and a corresponding second opposed sidewalls of the second trench.

16. The flash memory device as claimed in claim 12, further comprising insulating spacers between the control gates and the common source line.

17. The flash memory device as claimed in claim 12, wherein the common source line comprises a conductive material that is continuous with an adjacent common source diffusion region.

18. The flash memory device as claimed in claim 12, wherein the second trench is below the middle of the first trench between the pair of floating gates.

19. The flash memory device as claimed in claim 12, wherein the second trench is in the substrate, in a bottom surface of the first trench.

20. The flash memory device as claimed in claim 12, wherein the flash memory device has a split gate structure.
